(19) United States
(12) Patent Application Publication
(10) Pub. No.: US 2025/0081688 A1
(43) Pub. Date: Mar. 6, 2025

(54) DISPLAY APPARATUS COMPRISING DISPLAY MODULE AND MANUFACTURING METHOD THEREFOR

(71) Applicant: SAMSUNG ELECTRONICS CO., LTD., Suwon-si (KR)

(72) Inventors: Mingyu LEE, Suwon-si (KR); Eunhye KIM, Suwon-si (KR); Sangmoo PARK, Suwon-si (KR); Jamyeong KOO, Suwon-si (KR); Sera KWON, Suwon-si (KR); Byunghoon LEE, Suwon-si (KR); Yoonsuk LEE, Suwon-si (KR); Changkyu CHUNG, Suwon-si (KR)

(73) Assignee: SAMSUNG ELECTRONICS CO., LTD., Suwon-si (KR)

(21) Appl. No.: 18/951,127

(22) Filed: Nov. 18, 2024

Related U.S. Application Data
(63) Continuation of application No. PCT/KR2023/004549, filed on Apr. 5, 2023.

(30) Foreign Application Priority Data
May 31, 2022 (KR) 10-2022-0067226
Sep. 30, 2022 (KR) 10-2022-0125841

(51) Int. Cl. H01L 33/56; H01L 25/075; H01L 33/62

(52) U.S. Cl. CPC H10H 20/854; H01L 25/0753; H10H 20/857; H10H 20/0364

(57) ABSTRACT

A display module includes a plurality of inorganic light-emitting elements, a substrate including a mounting surface on which the plurality of inorganic light-emitting elements are mounted, and a non-conductive film (NCF) disposed on the substrate and configured to bond the plurality of inorganic light-emitting elements to the substrate. The NCF may have a black-based color.

### CROSS-REFERENCE TO RELATED APPLICATIONS

This application is a continuation of International Application No. PCT/KR2023/004549, filed on Apr. 5, 2023, which is based on and claims priority to Korean Patent Application 10-2022-0067226, filed on May 31, 2022, in the Korean Intellectual Property Office, and Korean Patent Application 10-2022-0125841, filed on Sep. 30, 2022, in the Korean Intellectual Property Office, the disclosures of which are incorporated by reference herein in their entireties.

### BACKGROUND

### 1. Field

The present disclosure relates to a display module comprising an inorganic light-emitting element and a method of manufacturing the same.

### 2. Description of the Related Art

In general, a display device is a type of output device that visually displays data information such as text, shapes, images, and the like.

A micro light-emitting diode (LED) display panel includes a plurality of inorganic LEDs, each of which is 100 micrometers or less in size. The micro LED panel is a self-emissive panel and does not require a backlight. In addition, the micro LED panel is resistant to burn-in and has excellent luminance, resolution, power consumption, and durability.

Due to the very small size of an inorganic light-emitting element included in the micro LED panel, an electrical connection between the electrode of the inorganic light-emitting element and the electrode of the substrate may be unstable.

To improve the clarity of a screen, the micro LED panel may include a black matrix layer. The black matrix layer may include holes through which the inorganic light-emitting element passes. The respective holes are required to be larger than the inorganic light-emitting element, which may result in a region around the inorganic light-emitting element where the black matrix layer is not provided. The black matrix layer may not be provided over the entire area of a substrate except for the area where the inorganic light-emitting element is disposed, thereby limiting the improvement of the contrast or sharpness of the screen.

### SUMMARY

According to an aspect of the present disclosure, a display module includes a plurality of inorganic light-emitting elements, a substrate including a mounting surface on which the plurality of inorganic light-emitting elements are mounted, and a non-conductive film (NCF) disposed on the substrate and configured to bond the plurality of inorganic light-emitting elements to the substrate. The NCF may have a black-based color.

The NCF may be attached to the mounting surface of the substrate and cover the entire mounting surface of the substrate.

The plurality of inorganic light-emitting elements may be arranged directly on the NCF covering the entire mounting surface.

The substrate may include a pad electrode formed on the mounting surface, and each of the plurality of inorganic light-emitting elements may include a contact electrode configured to be electrically connected to the pad electrode.

A position of the contact electrode of each of the plurality of inorganic light emitting elements may correspond to a position of the pad electrode.

The contact electrode and the pad electrode may be electrically connected by applying heat and pressure to the plurality of inorganic light-emitting elements transferred onto the NCF.

The NCF may include a flux, and the contact electrode and the pad electrode may be electrically connected through a bump applied to the contact electrode or the pad electrode by a thermo compression process in which heat and pressure are applied to the plurality of inorganic light-emitting elements and the bump is melted.

The flux may be configured to remove an oxide film created when the bump is melted.

The plurality of inorganic light-emitting elements may include a red sub-pixel, a green sub-pixel, and a blue sub-pixel forming a single pixel, and the NCF may be configured to prevent light emitted from a portion of at least one of the red sub-pixel, the green sub-pixel, or the blue sub-pixel from interfering with light emitted from at least one of the remaining red sub-pixel, green sub-pixel, or blue sub-pixel.

The NCF may be made of a black pigment.

According to various embodiments of the present disclosure, the display module in which the connection between the electrode of the inorganic light-emitting element and the electrode of the substrate may be stabilized, and the method of manufacturing the same.

Further, according to various embodiments of the present disclosure, the display module may have improved optical characteristics by reducing crosstalk between the sub-pixels in the inorganic light-emitting element and the method of manufacturing the same.

### BRIEF DESCRIPTION OF THE DRAWINGS

Additional aspects will be set forth in part in the description which follows and, in part, will be apparent from the description, or may be learned by practice of the presented embodiments.

FIG. 1 is a view illustrating a display apparatus, according to various embodiments.

FIG. 2 is an exploded view illustrating a main configuration of the display apparatus shown in FIG. 1.

FIG. 3 is an enlarged cross-sectional view illustrating a partial configuration of a display module shown in FIG. 1.

FIG. 4 is a flow chart of a method of manufacturing the display module according to various embodiments.

FIG. 5 is a cross-sectional view illustrating a substrate of the display module according to various embodiments.

FIG. 6 is a cross-sectional view of a non-conductive film attached to the substrate of the display module according to various embodiments.

FIG. 7 is a cross-sectional view illustrating an inorganic light-emitting element transferred onto the non-conductive film of the display module according to various embodiments.

FIG. 8 is a cross-sectional view illustrating an electrical connection between the inorganic light-emitting element and the substrate by applying heat and pressure to the inorganic light-emitting element transferred onto the non-conductive film of the display module according to various embodiments.

FIG. 9 is a cross-sectional view illustrating a partial configuration of the display module manufactured according to a method of manufacturing a display module according to various embodiments.

### DETAILED DESCRIPTION

Various embodiments of the disclosure and terms used herein are not intended to limit the technical features described herein to specific embodiments, and should be understood to include various modifications, equivalents, or substitutions of the corresponding embodiments.

In describing of the drawings, similar reference numerals may be used for similar or related elements.

Further, the term used herein is for the purpose of describing embodiments and is not intended to limit and/or define the disclosure. The singular form of a noun corresponding to an item may include one or more of the items unless clearly indicated otherwise in a related context. It will be understood that when the terms “includes”, “comprises”, “including”, and/or “comprising” are used in the disclosure, they specify the presence of the specified features, figures, steps, operations, components, members, or combinations thereof, but do not preclude the presence or addition of one or more other features, figures, steps, operations, components, members, or combinations thereof.

Further, as used herein, terms such as “1st”, “2nd”, “primary”, “secondary” and the like, may be used to describe various configurations, but the configurations are not limited by these terms, and the terms are used only for the purpose of distinguishing one configuration from another. For example, a first configuration may be referred to as a second configuration, and similarly, a second configuration may be referred to as a first configuration, without departing from the scope of the disclosure. In addition, the term “and/or” includes any and all combinations of one or more of the associated listed items.

Further, as used in the disclosure, the terms “front”, “rear”, “top”, “bottom”, “side”, “left”, “right”, “upper”, “lower”, and the like are defined with reference to the drawings, and are not intended to limit the shape and position of any configuration.

A display module according to various embodiments may include a plurality of inorganic light-emitting elements, a substrate including a mounting surface on which the plurality of inorganic light-emitting elements are mounted, and a non-conductive film disposed on the substrate to bond the plurality of inorganic light-emitting elements to the substrate. The non-conductive film may be configured to have a color in the black range to reduce cross-talk caused by light emitted from the plurality of inorganic light-emitting elements interfering with each other after being reflected from the substrate.

The non-conductive film may be attached to the mounting surface of the substrate so as to cover the entire mounting surface of the substrate.

The plurality of inorganic light-emitting elements may be arranged on the non-conductive film covering the entire mounting surface, so that no spaced area may be provided between the plurality of inorganic light-emitting elements and the non-conductive film.

The substrate may include a pad electrode formed on the mounting surface.

Each of the plurality of inorganic light-emitting elements may include a contact electrode configured to be electrically connected to the pad electrode.

The plurality of inorganic light-emitting elements may be transferred onto the non-conductive film to allow the contact electrode and the pad electrode to be positioned to correspond to each other.

The contact electrode and the pad electrode may be electrically connected by applying heat and pressure to the plurality of inorganic light-emitting elements transferred onto the non-conductive film.

The non-conductive film may include a flux.

By a thermo compression process in which heat and pressure are applied to the plurality of inorganic light-emitting elements, a bump applied to the contact electrode or the pad electrode is melted, and the contact electrode and the pad electrode may be electrically connected through the melted bump.

An oxide film created when the bump is melted may be removed by the flux.

The plurality of inorganic light-emitting elements may include a red sub-pixel, a green sub-pixel, and a blue sub-pixel, which are forming a single pixel.

The non-conductive film may be configured to prevent light emitted from a portion of the red sub-pixel, the green sub-pixel, and the blue sub-pixel from interfering with light emitted from the remaining sub-pixels by being reflected from the substrate.

The above non-conductive film may be configured to include a black pigment to have a color in the black range.

Hereinafter, embodiments according to the present disclosure will be described in detail with reference to the attached drawings.

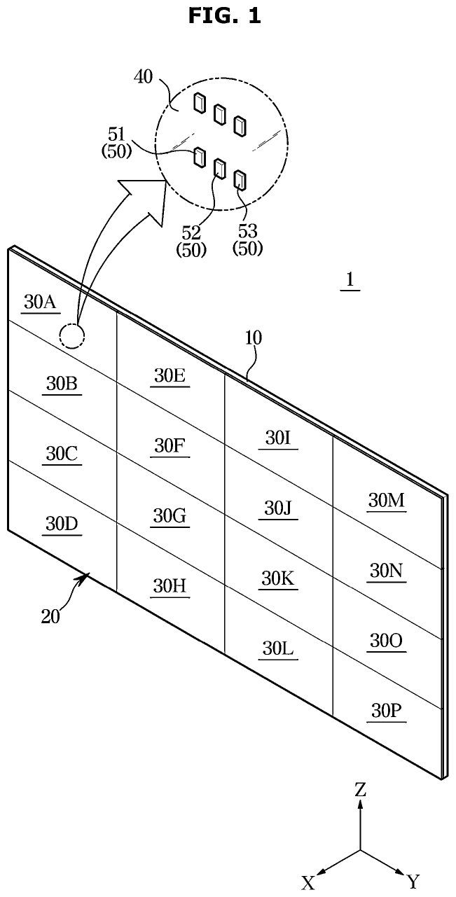

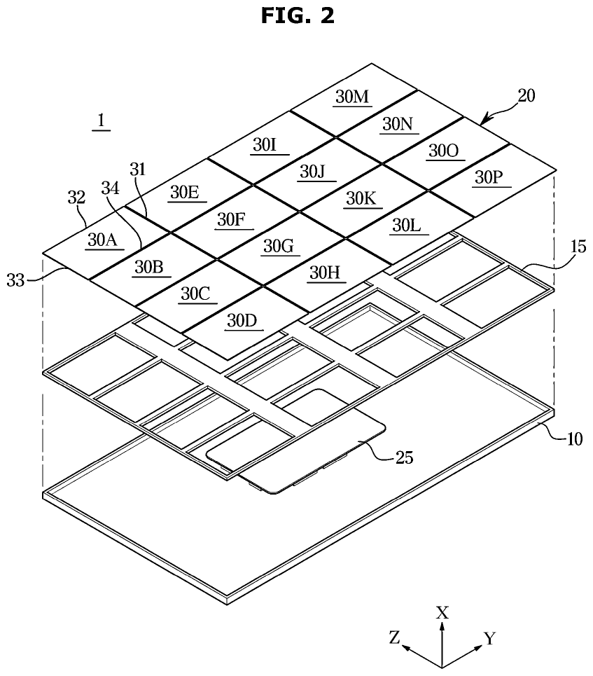

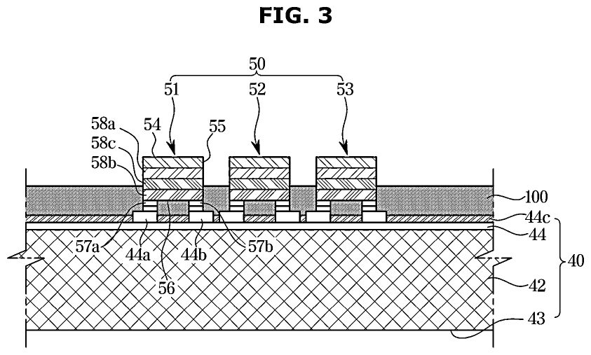

FIG. 1 is a view illustrating a display apparatus according to various embodiments. FIG. 2 is an exploded view illustrating a key configuration of the display apparatus shown in FIG. 1. FIG. 3 is an enlarged cross-sectional view illustrating a partial configuration of a display module shown in FIG. 1.

In the drawings, some configurations of a display apparatus 1, including a plurality of inorganic light-emitting elements 50, are micro-scale configurations having a size of a few μm to hundreds of μm, and for ease of description, the scale of some configurations (e.g., the plurality of inorganic light-emitting elements 50) may be exaggerated.

The display apparatus 1 may be a device that displays information, materials, data, and the like as characters, shapes, graphs, images, and the like, and the display apparatus 1 may be implemented as a television (TV), a personal computer (PC), a mobile phone, a digital signage, and the like.

According to various embodiments, as shown in FIGS. 1 and 2, the display apparatus 1 may include a display panel 20 that displays an image, a power supply that supplies power to the display panel 20, a main board 25 that controls the overall operation of the display panel 20, a frame 15 that supports the display panel 20, and a rear cover 10 that covers a rear side of the frame 15.

The display panel 20 may include a plurality of display modules 30A-30P, a drive board to drive each of the display modules 30A-30P, and a timing controller (TCON) board to generate timing signals necessary to control each of the plurality of display modules 30A-30P.

The rear cover 10 may support the display panel 20. The rear cover 10 may be placed on a floor via a stand, or may be mounted on a wall via a hanger.

The plurality of display modules 30A-30P may be arranged up, down, left and right so as to be adjacent to each other. The plurality of display modules 30A-30P may be arranged in an M*N matrix. In the present embodiment, the plurality of display modules 30A-30P are arranged in a 4*4 matrix with 16 display modules, but there is no limitation on the number and arrangement of the plurality of display modules 30A-30P.

The plurality of display modules 30A-30P may be mounted to the frame 15. The plurality of display modules 30A-30P may be mounted to the frame 15 by various methods known in the art, such as a magnetic force using a magnet, a mechanical fitting structure, and the like. The rear cover 10 may be coupled to the rear side of the frame 15, which may form a rear exterior of the display apparatus 1.

The rear cover 10 may include a metallic material. Accordingly, heat generated by the plurality of display modules 30A-30P and the frame 15 may be easily conducted to the rear cover 10, thereby increasing the heat dissipation efficiency of the display apparatus 1.

As described above, the display apparatus 1 according to various embodiments may realize a large screen by tiling the plurality of display modules 30A-30P.

In contrast to the various embodiment described above, the respective display modules in the plurality of display modules 30A-30P may be applied to a display apparatus. As a single unit, the display modules 30A-30P may be installed and applied to a wearable device, a portable device, a handheld device, and various other electronic products or electrical components requiring a display. In addition, as in the embodiment described above, it may be applied to a display apparatus, such as a PC monitor, a high-resolution TV, and a signage, an electronic display, and the like through a plurality of assembly arrangements in a matrix type.

The plurality of display modules 30A-30P may have the same configuration as each other. Accordingly, the description of any one display module described herein may be equally applicable to all of the other display modules.

Since all of the plurality of display modules 30A-30P are configured identically, each of the plurality of display modules 30A-30P will be described below with reference to a first display module 30A.

To avoid redundant description, the configuration of the plurality of display modules 30A-30P will be described in terms of a display module 30 and a substrate 40.

As an example, the first display module 30A of the plurality of display modules 30A-30P may be formed in a quadrangle type. The first display module 30A may be provided in a rectangular shape or a square type. Accordingly, the first display module 30A may include edges 31, 32, 33, and 34 formed in the up, down, left, and right directions with respect to a first direction X, which is the front.

Referring to FIG. 3, the plurality of display modules 30A-30P may each include the substrate 40 and the plurality of inorganic light-emitting elements 50 mounted on the substrate 40. The plurality of inorganic light-emitting elements 50 may be mounted on a mounting surface 41 of the substrate 40 facing in the first direction X.

The substrate 40 may be formed in a quadrangle type. As described above, the plurality of display modules 30A-30P may each be provided in a quadrangle shape, and the substrate 40 may also be formed in a quadrangle shape correspondingly. The substrate 40 may be provided in a rectangular shape or a square shape.

The substrate 40 may include a substrate body 42, the mounting surface 41 forming one side of the substrate body 42, and a rear surface 43 forming the other side of the substrate body 42 and disposed opposite to the mounting surface 41.

The substrate 40 may include a thin film transistor (TFT) layer 44 formed on the substrate body 42 to drive the inorganic light-emitting elements 50. The substrate body 42 may include a glass substrate. The substrate 40 may include a chip on glass (COG) type substrate. The substrate 40 may include a first pad electrode 44a and a second pad electrode 44b that are arranged to electrically connect the inorganic light-emitting elements 50 to the TFT layer 44.

The TFTs configuring the TFT layer 44 may not be limited to any particular structure or type, and may be configured in various embodiments. The TFTs in the TFT layer 44 according to various embodiments may be implemented as low temperature poly silicon (LTPS) TFTs, oxide TFTs, Si (e.g., poly silicon or a-silicon) TFTs, as well as organic TFTs, graphene TFTs, and the like.

In addition, the TFT layer 44 may be replaced by complementary metal-oxide-semiconductor (CMOS) type or n-type metal-oxide-semiconductor field effect transistor (MOSFET), or p-type MOSFET transistor when the substrate body 42 of the substrate 40 is fabricated with a silicon wafer.

The plurality of inorganic light-emitting elements 50 may be formed from an inorganic material, and may include inorganic light-emitting elements each having a size of a few μm to several tens of μm in width, length, and height, respectively. The micro inorganic light-emitting elements may have a size of 100 μm or less in a short side of the width, length, and height. In other words, the inorganic light-emitting elements 50 may be picked up from a sapphire or silicon wafer and directly transferred onto the substrate 40. The plurality of inorganic light-emitting elements 50 may be picked up and transported by an electrostatic method using an electrostatic head, or by a stamping method using an elastic polymer material, such as polydimethylsiloxane (PDMS), silicon, or the like, as the head.

The plurality of inorganic light-emitting elements 50 may be a light emitting structure including an n-type semiconductor 58a, an active layer 58c, a p-type semiconductor 58b, a first contact electrode 57a, and a second contact electrode 57b.

One of the first contact electrode 57a and the second contact electrode 58b may be electrically connected to the n-type semiconductor 58a, and the other is electrically connected to the p-type semiconductor 58b.

The first contact electrode 57a and the second contact electrode 57b may be in the form of a flip chip arranged horizontally and facing the same direction (opposite to a direction of light emission).

When mounted on the mounting surface 41, the inorganic light-emitting element 50 may have a light emitting surface 54 disposed toward the first direction X, a side surface 55, and a bottom surface 56 disposed on the opposite side of the light emitting surface 54. The first contact electrode 57a and the second contact electrode 57b may be formed on the bottom surface 56 of the inorganic light-emitting element 50.

The contact electrodes 57a and 57b of the inorganic light-emitting element 50 may be disposed on the opposite side of the light emitting surface 54. Accordingly, they may be disposed on the opposite side of the direction in which light is emitted.

The contact electrodes 57a and 57b may be arranged to face the mounting surface 41 and may be electrically connected to the TFT layer 43. The light emitting surface 54, which emits light in a direction opposite to the direction in which the contact electrodes 57a and 57b are arranged, may be arranged.

By the above arrangement, when the light generated by the active layer 58c is emitted in the first direction X through the light emitting surface 54, the light may be emitted in the first direction X without interference from the first contact electrode 57a or the second contact electrode 57b.

The first contact electrode 57a and the second contact electrode 57b may be electrically connected to the first pad electrode 44a and the second pad electrode 44b formed on the mounting surface 41 side of the substrate 40, respectively.

The plurality of inorganic light-emitting elements 50 may include a red light-emitting element 51, a green light-emitting element 52, and a blue light-emitting element 53. The light emitting elements 50 may be mounted on the mounting surface 41 of the substrate 40 as a series of red light emitting elements 51, green light emitting elements 52, and blue light emitting elements 53 as a unit. A series of red light-emitting elements 51, green light-emitting elements 52, and blue light-emitting elements 53 may form a single pixel. At this time, the red light-emitting element 51, the green light-emitting element 52, and the blue light-emitting element 53 may each form a sub-pixel.

The red light-emitting element 51, the green light-emitting element 52, and the blue light-emitting element 53 may be arranged in a row and spaced apart at predetermined intervals, as shown in FIG. 3. The red light-emitting element 51, the green light-emitting element 52, and the blue light-emitting element 53 may also be arranged in other shapes, such as a triangular shape.

According to various embodiments, the inorganic light-emitting element 50 may be coupled to the substrate 40 via a non-conductive film (NCF) 100. The contact electrodes 57a and 57b of the inorganic light-emitting element 50 may be electrically connected to the pad electrodes 44a and 44b, by a thermo compression process. The NCF 100 may be provided to not only physically bond the inorganic light-emitting element 50 to the substrate 40, but also electrically connect the inorganic light-emitting element 50 and the substrate 40.

The NCF 100 may include flux. A bump may be applied to the contact electrodes 57a and 57b of the inorganic light-emitting element 50 and/or the pad electrodes 44a and 44b of the substrate 40. In response to heat and pressure being applied to the inorganic light-emitting element 50 transferred onto the NCF 100, the bump may be melted and the contact electrodes 57a and 57b and the pad electrodes 44a and 44b may be electrically connected via the melted bump. The oxide film formed when the bump is melted may be removed by the flux described above.

According to various embodiments, the NCF 100 may be provided to have a color in the black range. For example, the NCF 100 may have a black-based color by including a black-based pigment. However, the present disclosure is not limited thereto and the NCF 100 may have a color in the black range by a variety of methods.

The NCF 100 may have a black color. The black colored NCF 100 may prevent light interference between sub-pixels when the inorganic light-emitting element 50 is emitted. In particular, light emitted from sub-pixels of a portion of the red light-emitting element 51, the green light-emitting element 52, and the blue light-emitting element 53 may be prevented from interfering with light emitted from the remaining sub-pixels by being reflected from the substrate 40. In other words, cross-talk phenomenon may be reduced or eliminated when the inorganic light-emitting element 50 is emitted, thereby improving the optical characteristics of the display apparatus 1.

In the event that the NCF 100 is made transparent or has a color that allows light to pass through, optical interference may occur between sub-pixels. For example, light emitted from the red light-emitting element 51 may be reflected from the substrate 40 to cause interference with light emitted from the green light-emitting element 52 and/or the blue light-emitting element 53. Similarly, light emitted from the green light-emitting element 52 may be reflected from the substrate 40 to cause interference with light emitted from the red light-emitting element 51 and/or the blue light-emitting element 53, and light emitted from the blue light-emitting element 53 may be reflected from the substrate 40 to cause interference with light emitted from the red light-emitting element 51 and/or the green light-emitting element 52. Such optical interference is referred to as cross-talk, and cross-talk may degrade the clarity of the image quality of the display apparatus 1.

As described above, in the display apparatus 1 according to various embodiments, the inorganic light-emitting element 50 may be coupled to the substrate 40 via the NCF 100 with a black color. By providing the NCF 100 with a black color, the cross-talk described above may be reduced or eliminated. In addition, the NCF 100 may act as an adhesive to bond the inorganic light-emitting element 50 to the substrate 40.

Conventionally, an anisotropic conductive film (ACF) has been used to bond the inorganic light-emitting element 50 to the substrate 40. The ACF has a structure in which an anisotropic conductive adhesive is attached to an upper face of a protective film and conductive balls are dispersed in an adhesive resin. The conductive balls are conductive spheres surrounded by a thin insulating film, which may electrically connect conductors to each other by breaking the insulating film under pressure.

However, when the ACF is used, the electrical connection between the contact electrodes 57a and 57b of the inorganic light-emitting element 50 and the pad electrodes 44a and 44b of the substrate 40 may be unstable. This is because that since the conductive balls are irregularly scattered within the ACF, if an insufficient number of conductive balls are positioned between the contact electrodes 57a and 57b and the pad electrodes 44a and 44b, the contact electrodes 57a and 57b and the pad electrodes 44a and 44b are not electrically connected. Since the inorganic light-emitting element 50 is very small in size, and the contact electrodes 57a and 57b of the inorganic light-emitting element 50 are even smaller, the electrical connection between the inorganic light-emitting element 50 and the substrate 40 may become unstable when the inorganic light-emitting element 50 and the substrate 40 are conventionally bonded using the ACF.

In addition, conventionally, the ACF is used to bond the inorganic light-emitting element to the substrate, and then a black matrix layer is further disposed on the substrate. The black matrix layer may be configured to cover the entire mounting surface of the substrate, and include a plurality of holes through which the inorganic light-emitting element may pass. The black matrix layer may improve the contrast of the screen by absorbing ambient light and making the substrate appear black.

Since light emitted from the inorganic light-emitting element is absorbed by the black matrix layer when the black matrix layer covers the inorganic light-emitting element, the black matrix layer may include a plurality of holes corresponding to the size and position of the inorganic light-emitting element. Only when the size of each of the plurality of holes is larger than the size of the inorganic light-emitting element, the inorganic light-emitting element may pass through the holes. Therefore, there is a limit to the size of the holes provided in the black matrix layer. Ideally, the size of the holes provided in the black matrix layer should be exactly the same as the size of the inorganic light-emitting elements, but in practice, the size of the holes should be larger than that of the inorganic light-emitting elements.

The black matrix layer may be a configuration to reduce the cross-talk described above. If the size of the hole provided in the black matrix layer is larger than that of the inorganic light-emitting element, a region where the black matrix layer is not provided may be created around the inorganic light-emitting element. This region may allow light interference to occur between the sub-pixels 51, 52, and 53. In other words, cross-talk may occur.

According to various embodiments, after the NCF 100 provided in a black color is applied to the substrate 40, the inorganic light-emitting element 50 may be transferred onto the NCF 100. In addition, heat and pressure may be applied to the inorganic light-emitting element 50 transferred onto the NCF 100 to electrically connect the contact electrodes 57a and 57b of the inorganic light-emitting element 50 and the pad electrodes 44a and 44b of the substrate 40. The NCF 100 may electrically connect the inorganic light-emitting element 50 and the substrate 40 in addition to physically coupling them. In addition, the NCF 100 may function as the black matrix layer described above by being provided in a black color. The NCF 100 may improve the contrast or sharpness of the screen by eliminating or reducing light interference between the sub-pixels 51, 52, and 53.

Because the NCF 100 according to various embodiments does not include a plurality of holes for the inorganic light-emitting element 50 to pass through, the NCF 100 may cover the entire mounting surface 41 side of the substrate 40 without regions spaced apart from the inorganic light-emitting element 50. The NCF 100 may be disposed directly on the entire area of the substrate 40 except for the area where the inorganic light-emitting element 50 is disposed. As described above, the NCF 100, which functions as a black matrix layer, may cover the entire area of the substrate 40 without areas spaced apart from the inorganic light-emitting element 50, thereby eliminating or reducing cross-talk between the sub-pixels 51, 52, and 53.

The substrate 40 may further include a light absorbing layer 44c to improve contrast by absorbing ambient light. The light absorbing layer 44c may be formed on the entire mounting surface 41 side of the substrate 40. The light absorbing layer 44c may be formed between the TFT layer 43 and the NCF 100.

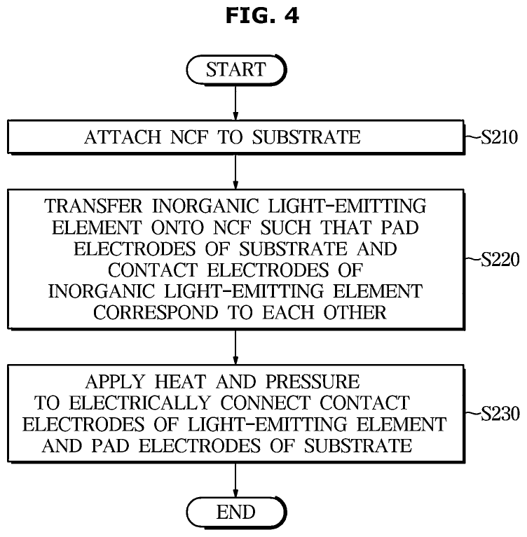

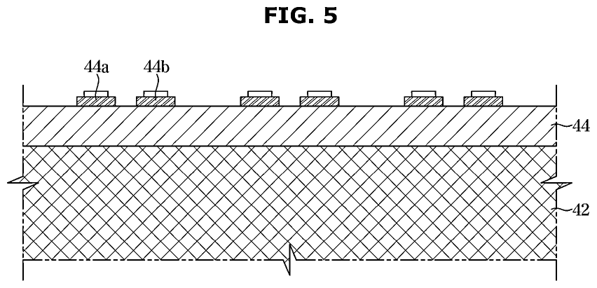

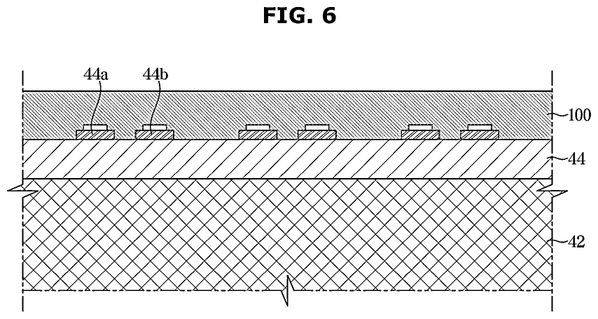

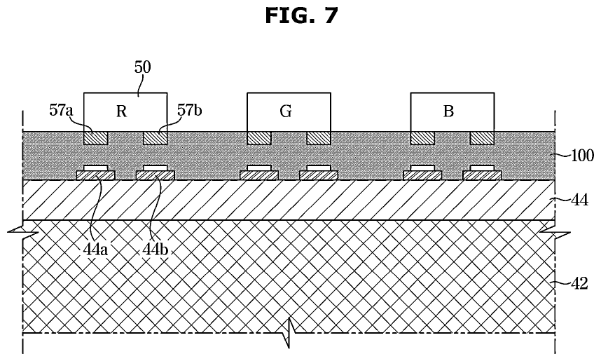

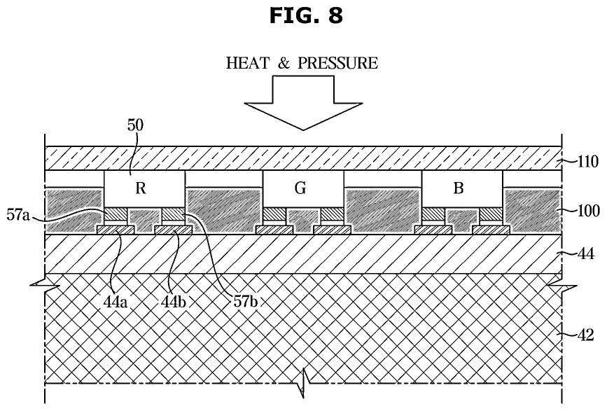

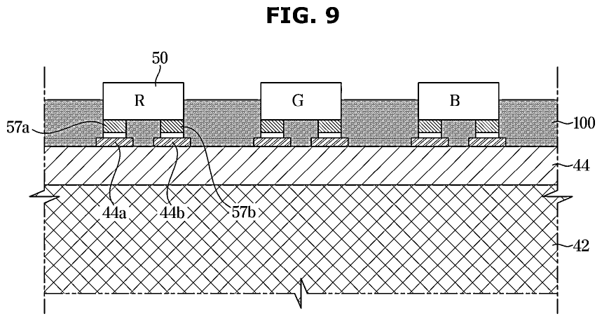

FIG. 4 is a flow chart to explain a method of manufacturing the display module according to various embodiments. FIG. 5 is a cross-sectional view illustrating the substrate of the display module according to various embodiments. FIG. 6 is a cross-sectional view of the NCF attached to the substrate of the display module according to various embodiments. FIG. 7 is a cross-sectional view illustrating the inorganic light-emitting element transferred onto the NCF of the display module according to various embodiments. FIG. 8 is a cross-sectional view illustrating an electrical connection between the inorganic light-emitting element and the substrate by applying heat and pressure to the inorganic light-emitting element transferred onto the NCF of the display module according to various embodiments. FIG. 9 is a cross-sectional view illustrating a partial configuration of the display module manufactured according to a method of manufacturing the display module according to various embodiments.

Hereinafter, a method for manufacturing a display module according to various embodiments will be described with reference to FIGS. 4 to 9.

Referring to FIG. 4, the method of manufacturing a display module according to various embodiments may include attaching the NCF 100 to the substrate 40 (S210), transferring the inorganic light-emitting element 50 onto the NCF 100 such that the pad electrodes 44a and 44b of the substrate 40 and the contact electrodes 57a and 57b of the inorganic light-emitting element 50 correspond to each other (S220), and applying heat and pressure to the inorganic light-emitting element 50 to electrically connect the contact electrodes 57a and 57b of the light-emitting element 50 and the pad electrodes 44a and 44b of the substrate 40 (S230).

Referring to FIGS. 5 and 6, the pad electrodes 44a and 44b may be formed on the TFT layer 44 of the substrate 40. The NCF 100 may be attached to the TFT layer 44 of the substrate 40. The NCF 100 may be provided to have a black color. The NCF 100 may be attached to the substrate 40 to cover the entire mounting surface 41 side of the substrate 40.

Referring to FIG. 7, after the NCF 100 is attached to the substrate 40, the inorganic light-emitting element 50 may be transferred onto the NCF 100. In particular, the inorganic light-emitting element 50 may be transferred onto the NCF 100 such that the contact electrodes 57a and 57b of the inorganic light-emitting element 50 correspond to the pad electrodes 44a and 44b of the substrate 40.

The inorganic light-emitting element 50 may be picked up from a sapphire or silicon wafer and directly transferred onto the NCF 100. The plurality of inorganic light-emitting elements 50 may be picked up and transported by an electrostatic method using an electrostatic head, or by a stamping method using an elastic polymer material, such as PDMS, silicon, or the like, as the head. The plurality of inorganic light-emitting elements 50 may be transferred onto the NCF 100 attached to the substrate 40 in a variety of ways other than the above.

Referring to FIG. 8, the contact electrodes 57a and 57b of the inorganic light-emitting elements 50 and the pad electrodes 44a and 44b of the substrate 40 may be electrically connected by applying heat and pressure to the plurality of inorganic light-emitting elements 50 transferred onto the NCF 100. As a configuration for applying heat and pressure to the inorganic light-emitting element 50, an ethylene-tetrafluoroethylene copolymer (ETFE) film 110 may be used. However, the present disclosure is not limited thereto. Films other than an ETFE film may be used to apply heat and pressure to the inorganic light-emitting element 50. For example, a film including at least one of a polymer, such as Teflon, polyimide, polyolefin, or the like may be used.

By the thermo compression process of applying heat and pressure to the inorganic light-emitting element 50, the bumps applied to the contact electrodes 57a and 57b of the inorganic light-emitting element 50 and/or the pad electrodes 44a and 44b of the substrate 40 may be melted. After melting the bumps, the contact electrodes 57a and 57b of the inorganic light-emitting element 50 and the pad electrodes 44a and 44b of the substrate 40 may be electrically connected. The oxide film created when the bumps are melted may be removed by the flux contained in the NCF 100.

Referring to FIG. 9, after the thermo compression process, the ETFE film 110 may be removed from the inorganic light-emitting element 50. As described above, the inorganic light-emitting element 50 may be electrically and physically connected to the substrate 40 by the thermo compression process. Using the process described above, a display module according to various embodiments may be manufactured.

Although certain exemplary embodiments are illustrated and described above, the present disclosure is not limited to the certain embodiments, various applications may of course be performed by those skilled in the art without deviating from what is claimed in the scope of claims, and such applications should not be understood separately from the technical idea or prospects herein.

What is claimed is:

1. A display module, comprising:
a plurality of inorganic light-emitting elements;
a substrate comprising a mounting surface on which the plurality of inorganic light-emitting elements are mounted; and
a non-conductive film (NCF) disposed on the substrate and configured to bond the plurality of inorganic light-emitting elements to the substrate,
wherein the NCF is a black-based color.

2. The display module of claim 1, wherein the NCF is attached to the mounting surface of the substrate and covers the entire mounting surface of the substrate.

3. The display module of claim 2, wherein the plurality of inorganic light-emitting elements are arranged directly on the NCF covering the entire mounting surface.

4. The display module of claim 1, wherein the substrate comprises a pad electrode formed on the mounting surface, and
wherein each of the plurality of inorganic light-emitting elements comprises a contact electrode configured to be electrically connected to the pad electrode.

5. The display module of claim 4, wherein a position of the contact electrode of each of the plurality of inorganic light emitting elements corresponds to a position of the pad electrode.

6. The display module of claim 5, wherein the contact electrode and the pad electrode are electrically connected by applying heat and pressure to the plurality of inorganic light-emitting elements transferred onto the NCF.

7. The display module of claim 6, wherein the NCF comprises a flux, and
wherein the contact electrode and the pad electrode are electrically connected through a bump applied to the contact electrode or the pad electrode by a thermo compression process in which heat and pressure are applied to the plurality of inorganic light-emitting elements and the bump is melted.

8. The display module of claim 7, wherein the flux is configured to remove an oxide film created when the bump is melted.

9. The display module of claim 1, wherein the plurality of inorganic light-emitting elements comprises a red sub-pixel, a green sub-pixel, and a blue sub-pixel forming a single pixel, and
wherein the NCF is configured to prevent light emitted from a portion of at least one of the red sub-pixel, the green sub-pixel, or the blue sub-pixel from interfering with light emitted from at least one of the remaining red sub-pixel, green sub-pixel, or blue sub-pixel.

10. The display module of claim 1, wherein the NCF is made of a black pigment.
